(19) United States
(12) Patent Application Publication
(10) Pub. No.: US 2015/0325477 A1
(43) Pub. Date: Nov. 12, 2015

(54) SUPER CONFORMAL METAL PLATING FROM COMPLEXED ELECTROLYTES

(71) Applicant: APPLIED Materials, Inc., Santa Clara, CA (US)

(72) Inventors: Roey Shaviv, Palo Alto, CA (US); Ismail T. Emesh, Sunnyvale, CA (US)

(73) Assignee: APPLIED Materials, Inc., Santa Clara, CA (US)

(21) Appl. No.: 14/274,611

(22) Filed: May 9, 2014

(51) Int. Cl. H01L 21/768; C25D 5/02

(52) U.S. Cl. CPC H01L 21/76879; H01L 21/76843; H01L 21/7685; H01L 21/76883; C25D 5/02

(57) ABSTRACT

A method for at least partially filling a feature on a workpiece generally includes obtaining a workpiece including a feature; and depositing a first layer in the feature, wherein the chemistry for depositing the first layer has a pH in the range of about 6 to about 13, and includes a metal complexing agent and at least one organic or inorganic additive selected from the group consisting of accelerator, suppressor, and leveler.

### BACKGROUND

The present disclosure relates to methods for electrochemically depositing a conductive material, for example, a metal, such as copper (Cu), cobalt (Co), nickel (Ni) gold (Au), silver (Ag), tin (Sn), aluminum (Al), and alloys thereof, in features (such as trenches and vias, particularly in Damascene applications) of a microelectronic workpiece.

An integrated circuit is an interconnected ensemble of devices formed within a semiconductor material and within a dielectric material that overlies a surface of the semiconductor material. Devices that may be formed within the semiconductor include metal-oxide-semiconductor transistors, bipolar transistors, diodes, and diffused resistors. Devices that may be formed within the dielectric include thin film resistors and capacitors. The devices are interconnected by conductor paths formed within the dielectric. Typically, two or more levels of conductor paths, with successive levels separated by a dielectric layer, are employed as interconnections. In current practice, copper and silicon oxide are commonly used for, respectively, the conductor and the low-K dielectric.

The deposits in a copper interconnect typically include a dielectric layer, a barrier layer, a seed layer, copper fill, and a copper cap. Because copper tends to diffuse into the dielectric material, barrier layers are used to isolate the copper deposit from the dielectric material. However, for other metal interconnects besides copper, barrier layers may not be required. Barrier layers are typically made of refractory metals or refractory compounds, for example, titanium (Ti), tantalum (Ta), titanium nitride (TiN), tantalum nitride (TaN), etc. Other suitable barrier layer materials may include manganese (Mn) and manganese nitride (MnN). The barrier layer is typically formed using a deposition technique called physical vapor deposition (PVD), but may also be formed by using other deposition techniques, such as chemical vapor deposition (CVD) or atomic layer deposition (ALD).

A seed layer may be deposited on the barrier layer. However, direct on barrier (DOB) deposition is also within the scope of the present disclosure, for example, barriers that are made from alloys or co-deposited metals upon which interconnect metals may be deposited without requiring a separate seed layer, such as manganese nitride (MnN), manganese nitride ruthenium (MnN,Ru), titanium ruthenium (TiRu), tantalum ruthenium (TaRu), tungsten ruthenium (WRu), nickel silicon (NiSi), and cobalt silicon (CoSi), as well as other barrier layers that are known and/or used by those having skill in the art.

In one non-limiting example, the seed layer may be a copper seed layer. As another non-limiting example, the seed layer may be a copper alloy seed layer, such as copper manganese, copper cobalt, or copper nickel alloys. In the case of depositing copper in a feature, there are several exemplary options for the seed layer. First, the seed layer may be a PVD copper seed layer. The seed layer may also be formed by using other deposition techniques, such as CVD or ALD.

Second, the seed layer may be a stack film, for example, a liner layer and a PVD seed layer. A liner layer is a material used in between a barrier and a PVD seed to mitigate discontinuous seed issues and improve adhesion of the PVD seed. Liners are typically noble metals such as ruthenium (Ru), platinum (Pt), palladium (Pd), osmium (Os), cobalt (Co) and nickel (Ni). Currently, CVD Ru and CVD Co are common liners; however, liner layers may also be formed by using other deposition techniques, such as ALD or PVD.

Third, the seed layer may be a secondary seed layer. A secondary seed layer is similar to a liner layer in that the secondary seed layer is typically formed from noble metals such as Ru, Pt, Pd, and Os, but the list may also include Co and Ni, and most commonly CVD Ru and CVD Co. (Like seed and liner layers, secondary seed layers may also be formed by using other deposition techniques, such as ALD or PVD.) The difference is that the secondary seed layer serves as the seed layer (for example in copper plating), whereas the liner layer is an intermediate layer between the barrier layer and the PVD seed.

After a seed layer has been deposited according to one of the examples described above, the feature may include a seed layer enhancement (SLE) layer, which is a thin layer of deposited metal, for example, copper having a thickness of about 2 nm. An SLE layer is also known as an electrochemically deposited seed (or ECD seed).

An ECD copper seed is typically deposited using a basic chemistry that includes a very dilute copper ethylenediamine (EDA) complex. ECD copper seed may also be deposited using other copper complexes, such as citrate, tartrate, urea, glycine, etc., and may be deposited in a pH range of about 2 to about 11, about 3 to about 10, or about 4 to about 10.

After a seed layer has been deposited according to one of the examples described above (which may also include an optional ECD seed), conventional ECD fill and cap may be performed in the feature, for example, using acid plating chemistry. Conventional ECD copper acid chemistry may include, for example, copper sulfate, sulfuric acid, methane sulfonic acid, hydrochloric acid, and organic additives (such as accelerators, suppressors, and levelers). Electrochemical deposition of copper has thus far been found to be a cost effective manner for depositing a copper metallization layer. In addition to being economically viable, ECD deposition techniques provide a substantially bottom up (e.g., nonconformal) metal fill that is mechanically and electrically suitable for interconnect structures.

Conventional ECD fill, particularly in small features, may result in a lower quality interconnect. For example, conventional ECD copper fill may produce voids, particularly in features having a size of less than 30 nm. As one example of a type of void formed using conventional ECD deposition, the opening of the feature may pinch off Other types of voids can also result from using the conventional ECD copper fill process in a small feature. Such voids and other intrinsic properties of a deposit formed using conventional ECD copper fill can increase the resistance of the interconnect, potentially slowing down the electrical performance of the device and deteriorating the reliability of the copper interconnect.

Therefore, there exists a need for an improved, substantially void-free metal fill process for a feature. Such substantially void-free metal fill may be useful in a small feature, for example, a feature having an opening size of less than 30 nm.

### SUMMARY

The summary is provided to introduce a selection of concepts in a simplified form that are further described below in the Detailed Description. The summary is not intended to identify key features of the claimed subject matter, nor to be used as an aid in determining the scope of the claimed subject matter.

In accordance with one embodiment of the present disclosure, a method for at least partially filling a feature on a workpiece is provided. The method includes obtaining a workpiece including a feature; and depositing a first layer in the feature, wherein the chemistry for depositing the first layer has a pH in the range of about 6 to about 13, and includes a metal complexing agent and at least one organic or inorganic additive selected from the group consisting of accelerator, suppressor, and leveler.

In accordance with another embodiment of the present disclosure, a method for at least partially filling a feature on a workpiece is provided. The method includes obtaining a workpiece including a feature; and electrochemically depositing a super conformal first layer in the feature, wherein the chemistry for depositing the first layer has a pH in the range of about 6 to about 10, and includes a metal complexing agent and at least one organic additive selected from the group consisting of accelerator, suppressor, and leveler.

In accordance with another embodiment of the present disclosure, a method for at least partially filling a feature on a workpiece is provided. The method includes obtaining a workpiece including a feature; depositing a barrier layer in the feature; depositing a seed layer in the feature; electrochemically depositing a conductive layer in the feature after the seed layer, wherein the conductive layer is a super conformal layer, and wherein the chemistry for depositing the conductive layer has a pH in the range of about 6 to about 13, and includes a metal complexing agent and at least one organic additive selected from the group consisting of accelerator, suppressor, and leveler; and annealing the workpiece to reflow the conductive layer in the feature.

In accordance with any of the embodiments described herein, the feature diameter may be less than 30 nm.

In accordance with any of the embodiments described herein, the first layer may be an electrochemically deposited metal super conformal layer.

In accordance with any of the embodiments described herein, the first layer may be at least a partially conformal conductive layer in the feature.

In accordance with any of the embodiments described herein, the metal complexing agent may be selected from the group consisting of ethylenediamine, glycine, citrate, tartrate, and urea.

In accordance with any of the embodiments described herein, the first layer may be deposited using a chemistry having a pH in a range of about 6 to about 12.

In accordance with any of the embodiments described herein, the temperature of the chemistry may be in the range of about 18 to about 60 degrees Celcius.

In accordance with any of the embodiments described herein, metal for the first layer may be selected from the group consisting of copper, cobalt, nickel, gold, silver, manganese, tin, aluminum, and alloys thereof.

In accordance with any of the embodiments described herein, the method may further include depositing a barrier layer in the feature before the first layer is deposited.

In accordance with any of the embodiments described herein, the first layer may be deposited directly on the barrier layer.

In accordance with any of the embodiments described herein, the method may further include depositing a seed layer in the feature before the first layer is deposited.

In accordance with any of the embodiments described herein, metal for the seed layer may be selected from the group consisting of copper, cobalt, nickel, gold, silver, manganese, tin, aluminum, ruthenium, and alloys thereof.

In accordance with any of the embodiments described herein, the seed layer may be selected from the group consisting of seed, secondary seed, and a stack film of seed and liner.

In accordance with any of the embodiments described herein, the method may further include thermally treating the workpiece to reflow the first layer in the feature.

In accordance with any of the embodiments described herein, the reflowed first layer may either partially or completely fill the feature.

In accordance with any of the embodiments described herein, thermally treating the workpiece may reduce the aspect ratio in the feature to be filled.

In accordance with any of the embodiments described herein, the method may further include depositing a second layer after the first layer, wherein the second layer is at least a partially conformal conductive layer, and thermally treating the workpiece to reflow the second layer.

In accordance with any of the embodiments described herein, the method may further include depositing a cap layer after the reflowed first layer.

In accordance with any of the embodiments described herein, the thermal treatment temperature may be in the range of about 100° C. to about 500° C.

### DESCRIPTION OF THE DRAWINGS

The foregoing aspects and many of the attendant advantages of the disclosure will become more readily appreciated by reference to the following detailed description, when taken in conjunction with the accompanying drawings, wherein:

FIG. 1A is a schematic flow diagram depicting a process and an exemplary feature development of an exemplary embodiment of the present disclosure;

FIG. 1B is a comparison schematic flow diagram depicting a process and an exemplary feature development according to a previously developed process;

FIG. 2 is a schematic of a chamfer void in a Damascene feature having a high aspect ratio;

FIG. 3 is a schematic flow diagram depicting a process and an exemplary feature development of an another exemplary embodiment of the present disclosure;

FIG. 4A is a schematic flow diagram depicting a process and an exemplary feature development of an another exemplary embodiment of the present disclosure;

FIG. 4B is a comparison schematic flow diagram depicting a process and an exemplary feature development according to a previously developed process;

FIGS. 5 and 6 are scanning electron microscopy (SEM) images of a plurality of features, using ECD super conformal copper chemistry in accordance with embodiments of the present disclosure; and

FIG. 7 includes a transmission electron microscopy (TEM) image of substantially void-free gap fill for a Damascene feature having a feature diameter of about 30 nm in accordance with embodiments of the present disclosure.

### DETAILED DESCRIPTION

Embodiments of the present disclosure are directed to workpieces, such as semiconductor wafers, devices or processing assemblies for processing workpieces, and methods of processing the same. The term workpiece, wafer, or semiconductor wafer means any flat media or article, including semiconductor wafers and other substrates or wafers, glass, mask, and optical or memory media, MEMS substrates, or any other workpiece having micro-electric, micro-mechanical, or microelectro-mechanical devices.

Processes described herein are to be used for metal or metal alloy deposition in features of workpieces, which include trenches and vias. In one embodiment of the present disclosure, the process may be used in small features, for example, features having a feature diameter of less than 30 nm. However, the processes described herein are applicable to any feature size. The dimension sizes discussed in the present application are post-etch feature dimensions at the top opening of the feature. The processes described herein may be applied to various forms of copper, cobalt, nickel, gold, silver, manganese, tin, aluminum, and alloy deposition, for example, in Damascene applications. In embodiments of the present disclosure, Damascene features may be selected from the group consisting of features having a size of less than 30 nm, about 5 to less than 30 nm, about 10 to less than 30 nm, about 15 to about 20 nm, about 20 to less than 30 nm, less than 20 nm, less than 10 nm, and about 5 to about 10 nm.

The descriptive terms “micro-feature workpiece” and “workpiece” as used herein include all structures and layers that have been previously deposited and formed at a given point in the processing, and is not limited to just those structures and layers as depicted in the figures.

Processes described herein may be modified to have an advantageous effect in metal or metal alloy deposition in Damascene features or in high aspect ratio features, for example, vias in through silicon via (TSV) features.

Although generally described as metal deposition in the present application, the term “metal” also contemplates metal alloys. Such metals and metal alloys may be used to form seed layers or to fully or partially fill the feature. Exemplary copper alloys may include, but are not limited to, copper manganese and copper aluminum. As a non-limiting example, the alloy composition ratio may be in the range of about 0.5% to about 6% secondary alloy metal, as compared to the primary alloy metal (e.g., Cu, Co, Ni, Ag, Au, etc.).

As described above, the conventional fabrication of metal interconnects may include a suitable deposition of a barrier layer on the dielectric material to prevent the diffusion of metal into the dielectric material. Suitable barrier layers, which may include, for example, Ta, Ti, TiN, TaN, Mn, or MnN. Suitable barrier deposition methods may include PVD, ALD and CVD; however, PVD is the most common process for barrier layer deposition. Barrier layers are typically used to isolate copper or copper alloys from dielectric material; however, in the case of other metal interconnects, diffusion may not be a problem and a barrier layer may not be required.

The barrier layer deposition may be followed by an optional seed layer deposition. However, a super conformal metal layer may be deposited directly on the barrier layer, i.e., without a seed layer.

In the case of depositing metal in a feature on a seed layer, there are several options for the seed layer. As described above, the seed layer may be (1) a seed layer (as a non-limiting example, a PVD copper seed layer). The seed layer may be a metal layer, such as copper, cobalt, nickel, gold, silver, manganese, tin, aluminum, ruthenium, and alloys thereof The seed layer may also be (2) a stack film of a liner layer and a seed layer (as a non-limiting example, a CVD Ru liner layer and a PVD copper seed layer), or (3) a secondary seed layer (as a non-limiting example, a CVD or ALD Ru or Co secondary seed layer). However, other methods of depositing these exemplary seed layers are contemplated by the present disclosure.

As discussed above, a liner layer is a material used in between a barrier layer and a seed layer to mitigate discontinuous seed issues and improve adhesion of the seed layer. Liners are typically noble metals such as Ru, Pt, Pd, and Os, but the list may also include Co and Ni. Currently, CVD Ru and CVD Co are common liners; however, liner layers may also be formed by using other deposition techniques, such as PVD or ALD. The thickness of the liner layer may be in the range of around 5 Å to 20 Å for Damascene applications.

Also discussed above, a secondary seed layer is similar to a liner layer in that the secondary seed layer is typically formed from noble metals such as Ru, Pt, Pd, and Os, but the list may also include Co and Ni, and most commonly CVD Ru and CVD Co. The difference is that the secondary seed layer serves as the seed layer, whereas the liner layer is an intermediate layer between the barrier layer and the seed layer. Secondary seed layers may also be formed by using other deposition techniques, such as PVD or ALD.

The liner or secondary seed deposit may be thermally treated or annealed at a temperature between about 100° C. to about 500° C. in a forming gas environment (e.g., 3-5% hydrogen in nitrogen or 3-5% hydrogen in helium) to remove any surface oxides and/or surface contaminants, increase the density the secondary seed or liner layer, and/or improve the surface properties of the deposit. The liner or secondary seed deposit may additionally be passivated by the soaking in gaseous nitrogen (N2 gas) or other passivating environments to prevent surface oxidation.

After a seed layer has been deposited (such as one of the non-limiting examples of PVD copper seed, PVD copper seed including CVD Ru liner, or CVD Ru secondary seed, or another deposition metal or metal alloy, layer combination, or deposition technique), the feature may be filled or partially filled with a conductor metal.

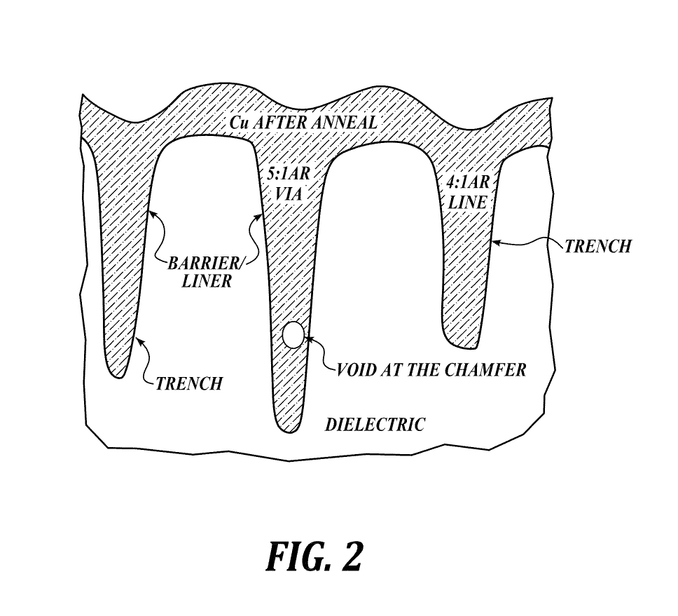

In vias having high aspect ratio, for example, greater than about 5:1, or greater than 7:1, the inventors have discovered that the via is susceptible to a void at the chamfer in the dual Damascene process. See, for example, an exemplary chamfer void in FIG. 2. Similarly, high aspect ratio lines with a reentrant profile may exhibit pinch-off at narrow openings or at line ends. In addition, via chains may exhibit pinch-off at narrow opening of the vias.

Metal features plated using conventional acid plating techniques are susceptible to these voiding problems, which is in part a result of the chemical kinetics of the plating process. In that regard, a high current is often used in such plating to facilitate rapid plating and good nucleation. Moreover, hot entry is often used to avoid seed corrosion. These current applications speed up the plating process. As a result, in small features (e.g., less than 30 nm), under rapid plating conditions, pinch-off often occurs before the bottom-up process is fully initiated.

To solve these problems, embodiments of the present disclosure provide a super conformal deposition process to reduce pinch-off and void formation. In another embodiment of the present disclosure, a post-plating annealing process may further improve void reduction in the feature.

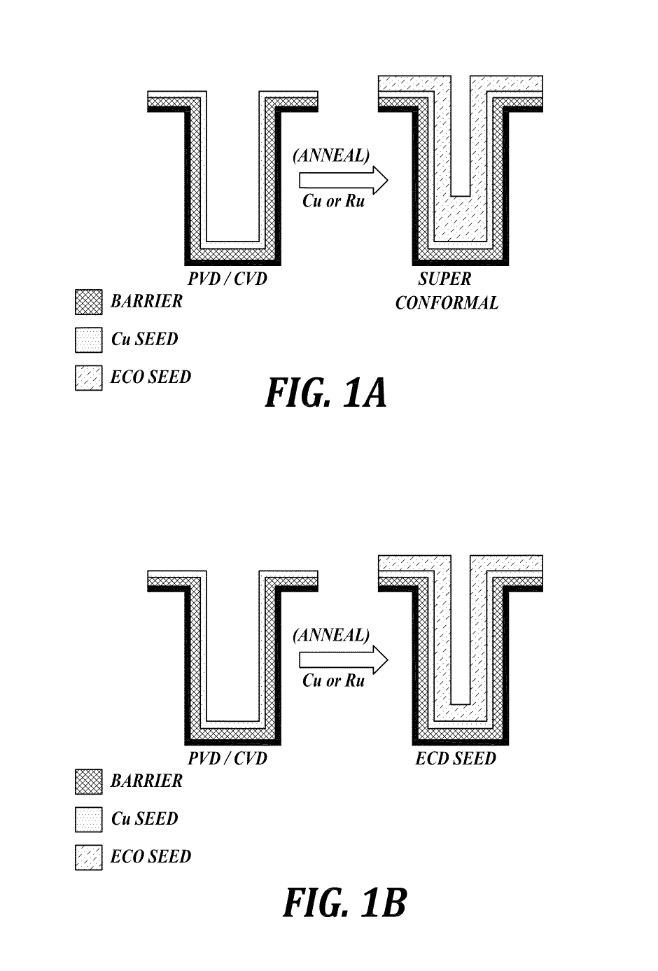

In accordance with one embodiment of the present disclosure, a process for super conformal deposition includes using organic additives (such as accelerators, suppressors, levelers, and any combination thereof) in an pH range of about 6 to about 13, complexed metal deposition process. An alkaline pH and complexed metal deposition process is typically used in an ECD seed process. As described above, an ECD seed layer is typically a conformal layer, for example, conformal ECD seed layer shown in FIG. 1B.

An exemplary ECD copper seed is typically deposited using a basic chemistry that includes a very dilute copper ethylenediamine (EDA) complex. As other non-limiting examples, the ECD seed layer may be a cobalt or nickel seed layer, deposited using a basic chemistry that includes a very dilute cobalt or nickel ethylenediamine complex. In one embodiment, the pH of the ECD seed chemistry may be in the range of about 6 to about 12.

An ECD super conformal layer may be deposited using a basic chemistry that includes a very dilute metal complex, similar to the chemistry used for ECD seed. For example, the ECD super conformal layer may be a copper, cobalt, or nickel layer, deposited using a basic chemistry that includes a very dilute metal ethylenediamine complex and organic additives. Other complexing agents besides a metal ethylenediamine complex may also be used, including, but not limited to glycine, citrate, tartrate, and urea.

A suitable pH range for ECD super conformal deposition may be in the range of about 6 to about 13, in one embodiment of the present disclosure about 6 to about 12, and in one embodiment of the present disclosure about 9.3. However, other chemistries may also be used to achieve conformal ECD super conformal deposition.

A suitable bath temperature may be in the range of about 18 degrees Celsius to about 60 degrees Celsius. In one embodiment of the present disclosure, the suitable bath temperature may be in the range of about 30 degrees Celsius to about 60 degrees Celsius. An elevated bath temperature may improve the thermodynamics and adsorption of the additives in the feature.

Organic additives are commonly used in conventional acid ECD fill and cap in a feature, for example, using an acid deposition chemistry. In that regard, conventional ECD copper acid chemistry may include, for example, copper sulfate, sulfuric acid, methane sulfonic acid, hydrochloric acid, and organic additives (such as accelerators, suppressors, and levelers). Electrochemical deposition of copper has been found to be a cost effective manner to deposit a copper metallization layer. In addition to being economically viable, the organic additives use in ECD deposition techniques provide for a substantially bottom up (e.g., nonconformal) metal fill that is mechanically and electrically suitable for interconnect structures.

The organic additives used in conventional ECD fill are generally not used in ECD seed deposition processes because conformal deposition (not bottom-up fill) is usually desirable in an ECD seed deposition process (see FIG. 1B). However, in accordance with embodiments of the present disclosure, the inventors have found that using such additives with ECD seed chemistry has an advantageous effect of encouraging some bottom-up fill (known as “super conformal” deposition), as opposed to pure conformal deposition, to effectively reduce the aspect ratio in a via. (Compare FIG. 1A showing super conformal ECD deposition with FIG. 1B showing conformal ECD seed deposition.)

Accordingly, the super conformal ECD deposition achieved by the processes described herein may be a hybrid layer that has both conformal deposition and bottom-up fill properties, as can be seen in FIG. 1A. The result is a feature with a reduced aspect ratio that has the advantageous effect of being less susceptible to void formation at the chamfer.

Referring to FIG. 1A, in accordance with one embodiment of the present disclosure, an ECD super conformal layer is deposited using a chemistry having a pH in the range of about 6 to about 13, a complexing agent, and organic and inorganic additives, such as suppressors, levelers, and accelerators. The result of such chemistry for the ECD super conformal layer is a hybrid seed layer that has both conformal deposition and bottom-up fill properties to help reduce the aspect ratio of the via during the fill process.

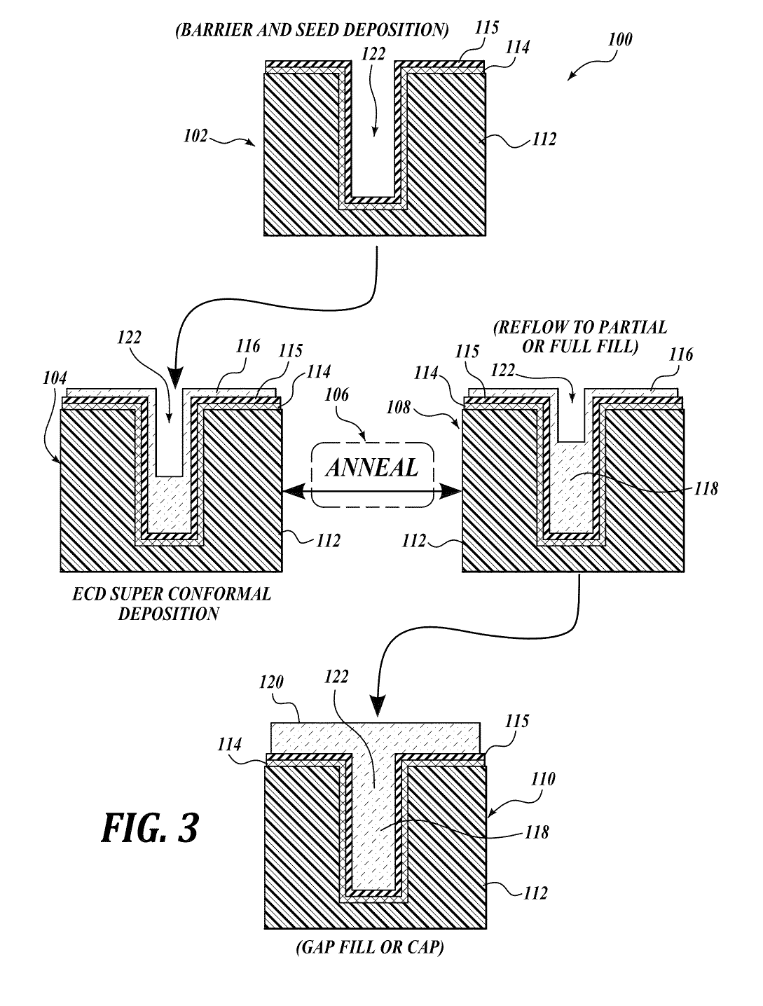

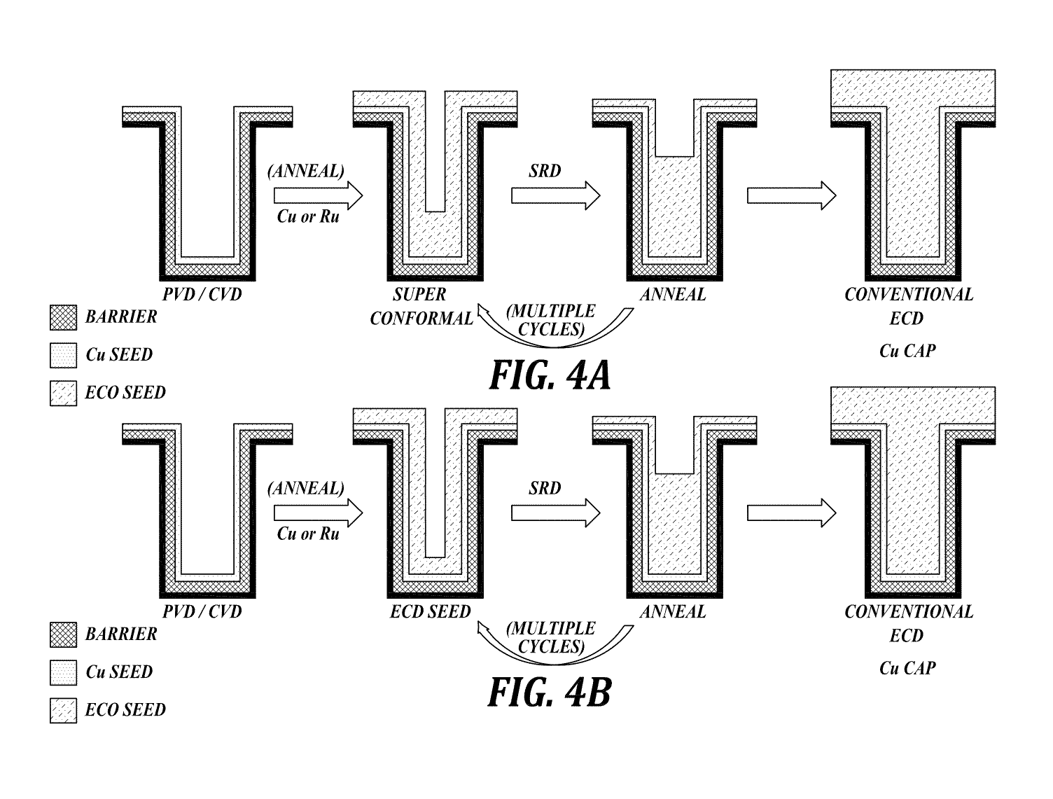

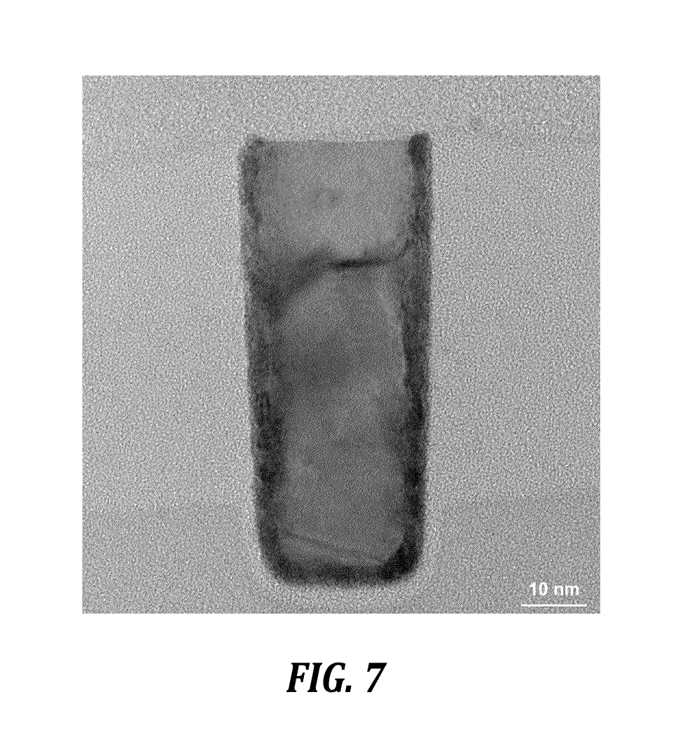

Referring to FIGS. 3 and 4A, the ECD super conformal layer can be thermally treated or annealed to reflow the ECD super conformal layer and at least partially fill the feature. The thermal treatment process provide an advantageous effect of further void reduction. See an image of substantially void-free fill after anneal in a small feature in FIG. 7. Subsequent ECD seed or super conformal layers may be deposited and thermally treated or annealed to further fill the feature. Subsequent layers may be deposited using chemistry that may or may not include organic additives.

Suitable additives in accordance with embodiments of the present disclosure may include one or more of an accelerator, suppressor, and leveler. In one embodiment of the present disclosure, suitable additives include an accelerator and a leveler.

Suitable accelerators include bis(sodium-sulfopropyl) disulfide (SPS), 3-mercapto-1-propanesulfonic acid (MPS), N,N-dimethyl-dithiocarbamyl propylsulfonic acid sodium salt, 3-(2-benzothiazolyl thio)-1-propanesulfonic acid sodium salt, 3-S-isothiuronium propyl sulfonate (UPS), 8-hydroxy-7-iodo-5-quinolinsulfonic acid, 1-propane sulfonic acid, 3-(ethoxy-thioxomethyl)-thiol sodium salt (OPX), and other suitable accelerators. As a non-limiting example, an accelerator may be added to the ECD super conformal chemistry in a concentration in the range of about 2 to about 40 ppm. As another non-limiting example, an accelerator may be added to the ECD super conformal chemistry in a concentration in the range of about 2 to about 4 ppm.

In addition, potassium iodide (KI) or hydrogen chloride (HCl) may be used to enhance the adsorption of a suppressor to the metal surface. In accordance with embodiments of the present disclosure, KI may be added to the ECD super conformal chemistry in a concentration range of about 1 to about 10 ppm. As a non-limiting example, KI may be added to the ECD super conformal chemistry in a concentration of about 10 ppm. In accordance with embodiments of the present disclosure, HCl may be added to the ECD super conformal chemistry in a concentration range of about 10 to about 50 ppm.

Suitable levelers include commercially available commercially available NP5200 suppressor and leveler (DOW Chemicals), polyethyleneimide (PEI), polyethylene glycol (PEG), 1-(2hydroxyethyl)-2-imidazollidinethione 4-mercaptopyridine; and polymeric amines. In accordance with embodiments of the present disclosure, a leveler may be added to the ECD super conformal chemistry in a concentration range of about 1.0 to about 2.0 ml/L.

In addition to additives, the concentration of copper may be increased from standard concentrations to improve mass transport. In accordance with embodiments of the present disclosure, copper concentration in the ECD super conformal chemistry may be in a concentration range of about 2 mM to about 20 mM.

Process conditions may be controlled to further reduce void formation, such as temperature and pulse testing. For example, a reduced reflow temperature in the range of about 225 C to about 300 C may help reduce void formation. In addition, pulse waveform may help improve mass transport into the feature.

After an ECD super conformal layer has been deposited according to the conditions described above, the ECD super conformal layer can be annealed for reflow. Before thermal treatment, the workpiece may be subjected to the spin, rinse, and dry (SRD) process or other cleaning processes. The ECD super conformal layer may then be heated to an adequate anneal temperature to get the layer to reflow, but not too hot such that the workpiece or elements on the workpiece are damaged or degraded. For example, the temperature may be in the range of about 100° C. to about 500° C. for seed reflow in the features. Appropriate thermal treatment or annealing temperatures are in the range of about 100° C. to about 500° C., and may be accomplished with equipment capable of maintaining sustained temperatures in the range of about 200° C. to about 400° C., and at least within the temperature range of about 250° C. to about 350° C.

The thermal treatment or annealing process may be performed using a forming or inert gas, pure hydrogen, or a reducing gas such as ammonia (NH3). During reflow, the shape of the deposition changes, such that the metal deposit may pool in the bottom of the feature, as shown in FIGS. 3 and 4A. In addition to reflow during the thermal treatment process, the metal deposit may also grow larger grains and reduce film resistivity. An inert gas may be used to cool the workpiece after heating.

After the thermal treatment process has been completed to either partially or completely fill the feature, a conventional acid chemistry may be used to complete the deposition process for gap fill and cap deposition. Acid chemistry metal deposition is generally used to fill large structures and to maintain proper film thickness needed for subsequent polishing because conventional acid chemistry fill is typically a faster process than ECD seed or super conformal deposition, saving time and reducing processing costs.

As seen in FIGS. 3 and 4A, ECD super conformal deposition and reflow may be repeated to ensure complete filling of the feature. In that regard, processes described herein may include one or more ECD super conformal deposition, cleaning (such as SRD), and thermal treatment cycles.

### EXAMPLE 1

### Conventional Additive System

Using a dilute copper ECD super conformal chemistry of 0.002 M copper, the inventors found that the conventional additive system (accelerator, suppressor, and leveler) combined with the ECD super conformal chemistry was producing improved gap fill results. Therefore, responses from individual additives were further investigated.

### EXAMPLE 2

### Modified Additive System

After investigation of the responses from the individual additives, a mixture of an accelerator (SPS or OPX) and a leveler (NP5200) was found to provide some advantages in gap fill results in a dilute copper ECD super conformal chemistry of 0.002 M copper. The accelerator was found to provide accelerating effects and the leveler was found to provide suppressing effects in the ECD super conformal chemistry.

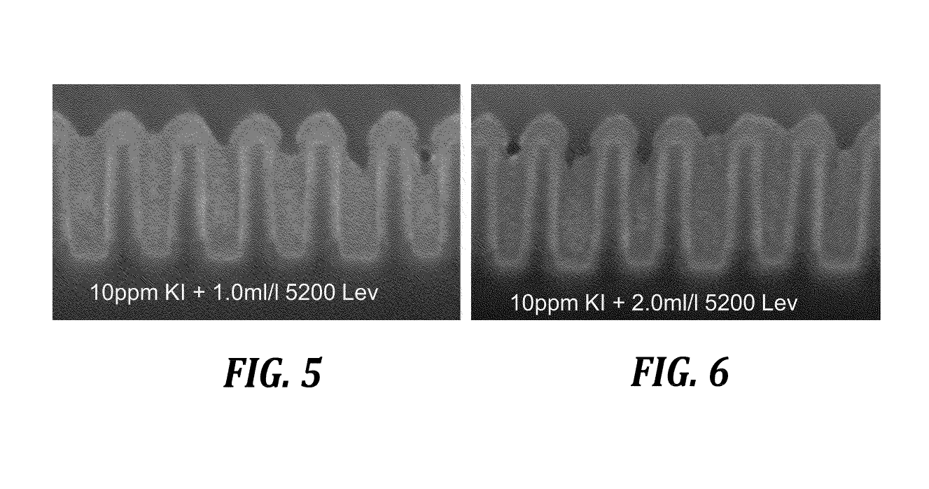

The additive combination of accelerator and leveler produced the signal of bottom up fill. However, some of the larger structures did not fill. See, for example, the TEM image in FIG. 5. Without wishing to be bound by theory, the inventors believe in a dilute copper, ECD super conformal bath was operating near a mass transport limited regime.

### EXAMPLE 3

### Pulse Testing

To address the problem of mass transport discussed in EXAMPLE 2 above, waveform pulse testing was investigated. A standard pulse of 10 ms “on” followed by 10 ms “off” was applied for a chemistry including 0.002 M copper, 2 ppm accelerator, and 1.0 ml/l leveler, and having a pH of 9.3. Comparatively, an increased pulse of 10 ms “on” followed by 40 ms “off” was applied for the same chemistry. The diffusion of copper into the structure of roughly 40 nm by 160 nm was approximated to take about 0.05 ms (with a diffusion coefficient for copper of 5.3×10[−6] cm2/s and a concentration of copper of 0.002 M). The change in pulse waveform did not significantly affect bottom-up fill.

### EXAMPLE 4

### Mass Transport

To address the problem of mass transport discussed in EXAMPLE 2 above, copper concentration will be increased to 0.1 M. Improved bottom-up fill results will be achieved using increased copper concentration in combination with additive concentrations of (1) 2 ppm accelerator and 1.0 ml/L leveler and (2) 2 ppm accelerator and 2.0 ml/L leveler, as shown in the predicted SEM images in FIG. 6.

While illustrative embodiments have been illustrated and described, various changes can be made therein without departing from the spirit and scope of the disclosure.

The embodiments of the disclosure in which an exclusive property or privilege is claimed are defined as follows:

1. A method for at least partially filling a feature on a workpiece, the method comprising:
(a) obtaining a workpiece including a feature; and
(b) depositing a first layer in the feature, wherein the chemistry for depositing the first layer has a pH in the range of about 6 to about 13, and includes a metal complexing agent and at least one organic or inorganic additive selected from the group consisting of accelerator, suppressor, and leveler.

2. The method of claim 1, wherein the feature diameter is less than 30 nm.

3. The method of claim 1, wherein the first layer is an electrochemically deposited metal super conformal layer.

4. The method of claim 1, wherein the first layer is at least a partially conformal conductive layer in the feature.

5. The method of claim 1, metal complexing agent is selected from the group consisting of ethylenediamine, glycine, citrate, tartrate, and urea.

6. The method of claim 1, wherein the temperature of the chemistry is in the range of about 18 to about 60 degrees Celcius.

7. The method of claim 1, wherein metal for the first layer is selected from the group consisting of copper, cobalt, nickel, gold, silver, manganese, tin, aluminum, and alloys thereof.

8. The method of claim 1, further comprising depositing a barrier layer in the feature before the first layer is deposited.

9. The method of claim 8, wherein the first layer is deposited directly on the barrier layer.

10. The method of claim 1, further comprising depositing a seed layer in the feature before the first layer is deposited.

11. The method of claim 10, wherein metal for the seed layer is selected from the group consisting of copper, cobalt, nickel, gold, silver, manganese, tin, aluminum, ruthenium, and alloys thereof.

12. The method of claim 10, wherein the seed layer is selected from the group consisting of seed, secondary seed, and a stack film of seed and liner.

13. The method of claim 1, further comprising thermally treating the workpiece to reflow the first layer in the feature.

14. The method of claim 13, wherein the reflowed first layer either partially or completely fills the feature.

15. The method of claim 13, wherein thermally treating the workpiece reduces the aspect ratio in the feature to be filled.

16. The method of claim 13, further comprising depositing a second layer after the first layer, wherein the second layer is at least a partially conformal conductive layer, and thermally treating the workpiece to reflow the second layer.

17. The method of claim 13, further comprising depositing a cap layer after the reflowed first layer.

18. The method of claim 13, wherein the thermal treatment temperature is in the range of about 100° C. to about 500° C.

19. A method for at least partially filling a feature on a workpiece, the method comprising:
(a) obtaining a workpiece including a feature; and
(b) electrochemically depositing a super conformal first layer in the feature, wherein the chemistry for depositing the first layer has a pH in the range of about 6 to about 10, and includes a metal complexing agent and at least one organic additive selected from the group consisting of accelerator, suppressor, and leveler.

20. A method for at least partially filling a feature on a workpiece, the method comprising:
(a) obtaining a workpiece including a feature;
(b) depositing a barrier layer in the feature;
(c) depositing a seed layer in the feature;
(d) electrochemically depositing a conductive layer in the feature after the seed layer, wherein the conductive layer is a super conformal layer, and wherein the chemistry for depositing the conductive layer has a pH in the range of about 6 to about 12, and includes a metal complexing agent and at least one organic additive selected from the group consisting of accelerator, suppressor, and leveler; and
(e) annealing the workpiece to reflow the conductive layer in the feature.
